(19) United States
(12) Patent Application Publication
(10) Pub. No.: US 2006/0146902 A1
(43) Pub. Date: Jul. 6, 2006

(54) Distributed feedback laser including AlGaInAs in feedback grating layer

(76) Inventors: Nobuyuki Ikoma, Yokohama-shi (JP); Takahiko Kawahara, Yokohama-shi (JP)

Correspondence Address: SMITH, GAMBRELL & RUSSELL, LLP, 1850 M STREET, N.W., SUITE 800, WASHINGTON, DC, 20036, US

(21) Appl. No.: 11/280,823

(22) Filed: Nov. 17, 2005

(30) Foreign Application Priority Data
Nov. 18, 2004 (JP) 2004-334961

(51) Int. Cl. H01S 5/00

(52) U.S. Cl. 372/43.01

(57) ABSTRACT

The present invention provides a distributed feedback laser diode (DFB-LD), in which the active region may be easily flattened. The active region of the invention is optically coupled with the feedback grating made of the n-type InP layer and the n-type AlGaInAs layer. Since both layers show the n-type conduction, the n-type impurities, which are typically silicon (Si), introduced from the ambient or tools may not increase the resistivity of the layers. Moreover, the difference in the refractive index between AlGaInAs and InP is greater than that between InGaAsP and InP. Accordingly, even when the magnitude of the undulation formed in the interface between AlGaInAs and InP is small, the coupling coefficient between the grating the active layer, which is equal to the product of the magnitude of the undulation H and the difference in the refractive index An, may be prevented from the extreme decrease.

### BACKGROUND OF THE INVENTION

1. Field of the Invention

The present invention related to a light-emitting device made of III-V compound semiconductor materials.

2. Related Prior Arts

A rapid increase of the mass to be transmitted by the optical communication requests a light-emitting device capable of modulating in high frequencies with a low price. A distributed feedback laser diode (DFB-LD) in a 1.3 μm wavelength band is one of solution to meet such requests. The DFB-LD is able to modulate in direct and to operate without any temperature-control means. Without temperature-controlling means, such as a Peltier device, the DFB-LD is required to show a good performance especially at high temperatures. The DFB-LD with an active layer made of AlGaInAs may show good characteristics at high temperatures.

The DFB-LD has a grating typically formed by burying the periodic undulation formed on the surface of the ground layer with another semiconductor layer having a composition different to that of the ground layer. This feedback grading is disposed above or below the active layer that emit light.

Nakahara et al. has disclosed, in Journal of lightwave technology 22(1), (2,004) pp. 159 to 165, a DFB-LD with a ridge waveguide structure, a feedback grating formed by the p-type InP and the p-type InGaAsP and an active region including a AlGaInAs multiple quantum well (MQW) coupled with the feedback grating. Kobayashi et. al has disclosed, in the proceeding of 15th Indium Phosphide and related materials, (2003) pp. 239 to 242, a DFB-LD with a buried hetero-structure that provides a feedback grating made of n-type InGaAsP and InP, and an active region including AlGaInAs with the MQW structure..

When the feedback grating is formed, the surface thereof is exposed to the ambient, which may cause a contamination of the surface by impurities such as silicon (Si) derived from the process tools. Since Si behaves as an n-type dopant in the III-V compound semiconductor such as InP, when p-type layers constitute the feedback grating, the Si atoms accumulated on the exposed surface reduce the hole concentration thereby increasing the resistivity of the layers. To increase the intrinsic resistance of the DFB-LD results in not only the increase of the driving voltage of the LD but also the increase of the operating temperature due to the large heat generated at the region Si impurities are accumulated, which degrades the performance of the DFB-LD. Nakahara has reported that the resistance at the hetero interface of the grating may be reduced by adjusting the composition of InGaAsP layer and the p-type doping concentration of InGaAsP and InP layers, both comprising the feedback grating. However, Nakahara has not mentioned nor suggested to reduce the influence of the impurities accumulated in the interface.

The band discontinuity may be formed at the interface between layers each constituting the feedback grating and having the composition different to each other. This band discontinuity causes the increase of the resistivity in a direction intersecting the interface. Generally in the III-V compound semiconductor material, the electron mobility is greater than the hole mobility, accordingly, when the electron is the majority carrier, the increase of the resistivity due to not only the hetero-interface between two materials may be suppressed but also the accumulation of the n-type impurities therein.

Kobayashi's DFB-LD includes feedback grating made of the n-type InGaAsP and the n-type InP, and the active layer disposed above this feedback grating with a large undulation in spite of the active layer, in particular the well layers thereof, is required to be flat enough in an atomic layer level. The Kobayashi has reported to obtain such flat semiconductor layer on the undulated feedback grating by adjusting the growth condition of the n-type InGaAsP and the n-type InP each constituting the grating.

Therefore, the present invention is to provide a laser diode that includes a feedback grating capable of obtaining an active layer formed thereon flat enough compared as a combination of the n-type InGaAsP and then n-type InP.

### SUMMARY OF THE INVENTION

According to one aspect of the present invention, a light-emitting device is to be provided. The light-emitting device of the invention comprises an n-type InP region, an n-type AlGaInAs layer disposed on this n-type InP region, and an active region disposed on the n-type AlGaInAs layer. A feedback grating is formed in the interface between the n-type InP region and the n-type AlGaInAs layer, and is optically coupled with the active region.

Since the preset light-emitting device provides the feedback grating made of n-type semiconductor material, the accumulation of n-type impurities in the interface may not decrease the majority carrier, electrons in this case. Moreover, since the hetero-interface between the n-type AlGaInAs and the n-type InP shows a smaller discontinuity in the conduction band and a larger difference in the refractive index compared with the conventional combination of InGaAsP and InP, the former effect may not disturb the transportation of the majority carrier, which suppresses, accompanied with the combination of the n-type materials, the increase of the resistivity along a direction intersecting the interface, and the latter effect makes the depth of the undulation at the interface smaller, which results in the easy process to bury the undulation to obtain a flattened surface for the active region disposed thereon.

The n-type AlGaInAs in the present light-emitting device may have a band gap wavelength greater than 1.07 μm, and smaller than 1.2 μm. By setting the band gap wavelength of the n-type AlGaInAs, the discontinuity of the conduction band may be smaller than 0.05 eV and the difference in the refractive index to the n-type InP may be greater than 0.15.

The present light-emitting device may further provide, in the active region thereof, first and second graded layers, first and second separated confinement hetero-structure (SCH) layers, and a quantum well region. Two SCH layers put the quantum well region therebetween, and two graded layers put the two SCH layers with the quantum well region therebetween. Moreover, the quantum well region may include a plurality of well layers and a plurality of barrier layers. These layers, the well layers, the barrier layers, two SCH layers, and two graded layers, may be made of AlGaInAs with compositions different to other layers. The well layers have the band gap wavelength about 1.4 μm. Thus, a distributed feedback (DFB) laser capable of emitting the single-mode light at comparably high temperatures can be obtained, in which the primary semiconductor material is AlGaInAs and the emission wavelength is in the 1.3 μm band.

### BRIEF DESCRIPTION OF DRAWINGS

FIG. 1 is a perspective view with partially exposing a section;

FIG. 2 shows a configuration of the active region;

FIG. 3 shows a band discontinuity of the conduction band between InGaAsP and InP, and that between AlGaInAs and InP against the band gap wavelength of InGaAsP and AlGaInAs, respectively;

FIG. 4 is shows a difference in the refractive index between InGaAsP and InP, and between AlGaInAs and InP at the wavelength of 1.3 μm;

FIGS. 5A to 5C show the process for manufacturing the DFB-LD of the present invention; and

FIGS. 6A and 6B shows the process, subsequent to the step shown in FIG. 5C, for manufacturing the DFB-LD of the present invention.

### DESCRIPTION OF PREFERRED EMBODIMENTS

Next, preferred embodiments of the present invention will be described as referring to accompanying drawings. In the specification and drawings, same symbols or numerals will refer the same elements without overlapping explanations.

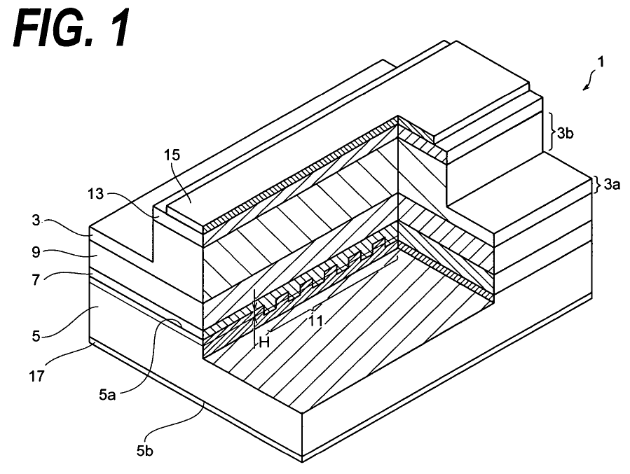

FIG. 1 is a perspective view with partially exposing a cross section of a semiconductor laser according to the present invention. The semiconductor laser (hereinafter denoted as LD) 1 includes a p-type layer 3, an n-type InP region 5, an n-type AlGaInAs layer 7, and an active region 9 put between the n-type InP region 5 and the p-type layer 3. The active region optically couples with a distributed feedback grating 11 comprised of the n-type InP region 5 and n-type AlGaInAs layer 7.

The feedback grating 11 may be formed by burying an undulation formed on the surface 5a of the n-type InP region 5 with the n-type AlGaInAs layer 7, and causes the optical diffraction by a difference in the refractive index between two regions, 5 and 7, and the magnitude of the undulation. The strength of the optical diffraction due to the coupling of the light generated in the active region 9 with the feedback grating 11 is expressed by the coupling coefficient, which considerably affects various characteristics of the LD with the feedback grating, which is called as the distributed feedback laser diode, DFB-LD, such as the threshold current, the emission efficiency, and the stability of the single mode operation thereof. The coupling coefficient may be nearly determined by the difference in the refractive index of two materials comprising the feedback grating and the magnitude of the undulation.

When the band gap wavelength of the n-type AlGaInAs layer 7 is 1.1 μm, a difference in the refractive index An between the n-type InP region 5, n ^{(InP)}, and that of the n-type AlGaIAs layer 7, n^{(AlGaInAs)}, becomes Δn =0.19, which is greater than that of the conventional combination of the InGaAsP and InP materials. The band gap wavelength denotes a wavelength corresponding to the fundamental absorption edge of a semiconductor material, that is, when the band gap energy of 1 eV corresponds to the band gap wavelength of 1.24 μm.

A large difference in the refractive index between the n-type AlGaInAs layer 7 and the n-type InP region 5 may result in the large coupling coefficient, which shows the lower threshold current and the higher stability in the single mode operation of the DFB-LD. Moreover, since the difference in the refractive index becomes greater, the undulation formed on the n-type InP region 5 and buried by the n-type AlGaInAs layer 7 may be made smaller, to obtain the same coupling coefficient, compared as the conventional grating buried by the InGaAsP layer. The smaller undulation makes it possible to obtain a flat surface of the n-type AlGaInAs layer 7. To make the surface of the n-type AlGaInAs layer 7, which is beneath the active region 9, flat enough by an atomic level, is a key point t obtain the active layer with high quality.

On the other hand, the electrical resistance in a direction intersecting the feedback grating 11 does not increase because two layers, 5 and 7, are made of n-type materials. That is, n-type impurities introduced at the process for the feedback grating does not reduce the majority carrier, electrons in this case, of the n-type AlGaInAs layer 7 and the n-type InP region 5.

The n-type AlGaInAs region 7 disposes the active region thereon, and the active region disposes the p-type layer 3 thereon. The LD 1 has the so-called ridge waveguide structure. The p-type layer 3 includes a planar portion 3a that covers the whole surface of the active region 9 and a stripe portion 3b disposed on the planar portion 3a. On the stripe portion 3b is formed with a contact layer 13 with an anode electrode 15 thereof. While, the n-type InP region 5 forms a cathode electrode 17 on a back surface 5b thereof.

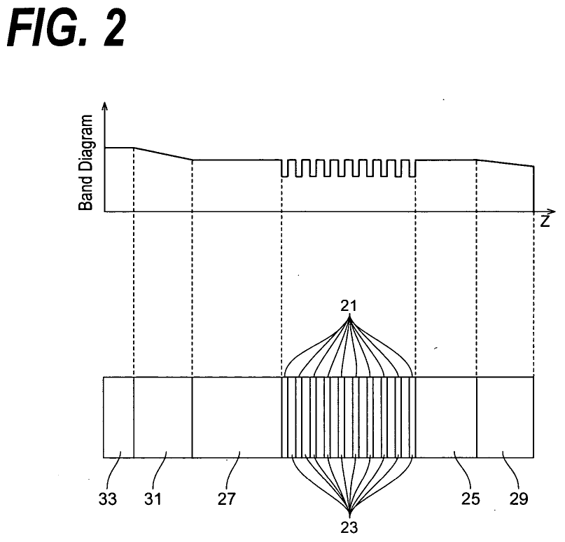

FIG. 2 is a cross section of the active region 9. The active region 9 of the present embodiment includes a plurality of well layers 21 and a plurality of barrier layers 23, each barrier layer 23 being put between well layers 21. The well and barrier layers, 21 and 23, are made of AlGaInAs, but compositions of each element are different in both layers. In the present embodiment, the band gap wavelength of the well layer 21 is 1.4 μm, while that of the barrier layer 23 is 1.05 μm. Here, the band gap wavelength is one index denoting the composition of the semiconductor material. The well layer 21 suffers a compressive strain of 1 %. These well and barrier layer, 21 and 23, are put between two SCH (Separated Confinement Hetero-structure) layers, 25 and 27. These two SCH layers, 25 and 27, are also made of AlGaInAs with the band gap wavelength of 1.05 μm.

The p-type layer 3 is, similar to the n-type InP layer 5, made of InP. The first SCH layer 25 and the n-AlGaInAs layer 7 put a graded layer 29, whose composition continuously varies from the first SCH layer 25 to the n-type AlGaInAs layer 7. The second SCH layer 27 accompanies a second graded layer 31 in the outer side thereof. The composition of the second graded layer 31 continuously varies from the second SCH layer 27 to a semiconductor layer 33 explained below. Two graded layers, 29 and 31, each removes the band discontinuity between the layers sandwiching the graded layers, 29 and 31, to reduce the resistivity along the direction intersecting the active region 9. The p-type InP layer 3 and the second graded layer 31 put the layer 33 made of AlInAs, which prevents electrons from overflowing into the p-type InP layer 3.

An exemplary arrangement of each layer is as following table:

TABLE
Typical arrangement of the DFB laser according to the
present invention

| | | | |
|---|---|---|---|
| Anode 15 | Ti/Pt/Au | | |
| contact layer 13 | InGaAs | 0.4 | μm |
| p-type layer 3 | p-InP | 2 | μm |
| active region 9 | | | |
| AlInAs layer | AlInAs | 20 | nm |
| second grader layer 31 | AlGaInAs | 80 | nm |
| second SCH layer 27 | AlGaInAs | 80 | nm |
| well layer 21 | 10 layers of AlGaInAs | 5 | nm |
| barrier layer 23 | 9 layers of AlGaInAs | 8 | nm |
| first SCH layer 25 | AlGaInAs | 40 | nm |
| first grade layer 29 | AlGaInAs | 40 | nm |
| n-type AlGaInAs layer 7 | n-AlGaInAs | 30 | nm |
| n-type region 5 | n-InP substrate | 100 | pm |
| Cathode 17 | AuGe/Ni/Au | | |

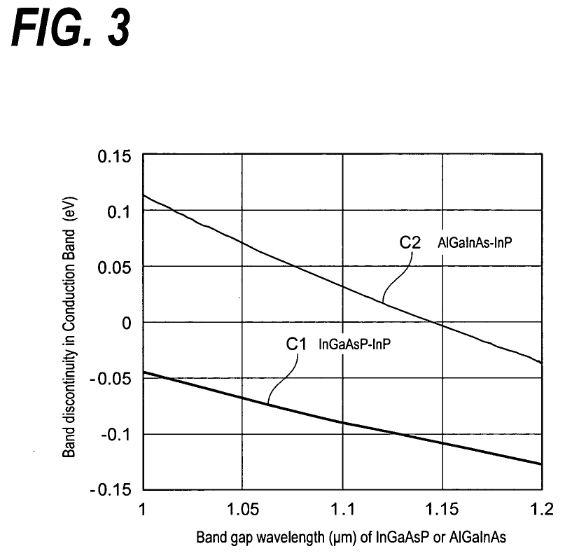

FIG. 3 shows the discontinuity in the conduction band between InGaAsP and InP (line C1), and that between AlGaInAs and InP (line C2), where the horizontal axis corresponds to the band gap wavelength (μm) of InGaAsP and AlGaInAs, respectively. For the n-type layer, which buries the feedback grating 11, it is preferable to have the band gap wavelength from 1.0 to 1.2 μm in the emission wavelength of 1.3 μm band. As shown in FIG. 3, the combination of InGaAsP and InP appears the band discontinuity in the conduction band below-0.05 eV, which means that the bottom of the conduction band of InGaAsP is lower than that of InP, in a whole range of the band gap wavelength from 1.0 to 1.2 μm. That is, the band discontinuity is greater than 0.05 eV in absolute in the combination of InGaAsP and InP.

While, for the combination of AlGaInAs and InP and in the band gap wavelength from 1.07 μm to 1.2 μm, the band discontinuity in the conduction band is less than 0. 05 eV in absolute, which means that the discontinuity in the conduction band may become smaller in the combination of AlGaInAs and InP compared to the combination of InGaAsP and InP. The small band discontinuity results in the low resistivity between layers, thereby reducing the threshold voltage and the heat generation of the LD due to the reduction of the resistance. The band gap wavelength of AlGaInAs is further preferable in a range from 1.1 μm to 1.2 μm to gain the band discontinuity less than 0.03 eV in absolute.

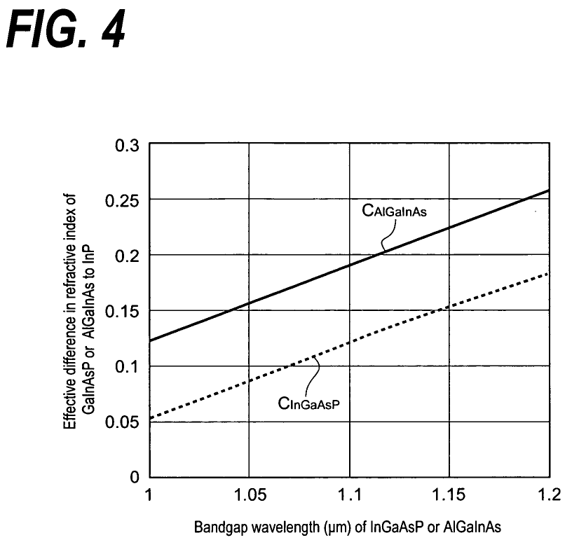

FIG. 4 shows the difference in the refractive index between InGaAsP and InP (C_{InGaASP}) and that between AlGaInAs and InP (C_{AlGaInAs}) in the wavelength band of 1.3 μm. The horizontal axis corresponds to the band gap wavelength of InGaAsP or AlGaInAs, while the vertical axis denotes the difference of the refractive index. Thus, the difference in the refractive index is always greater for the combination of AlGaInAs and InP than that for the combination of InGaAsP and InP in the range of the band gap wavelength from 1.0 to 1.2 μm.

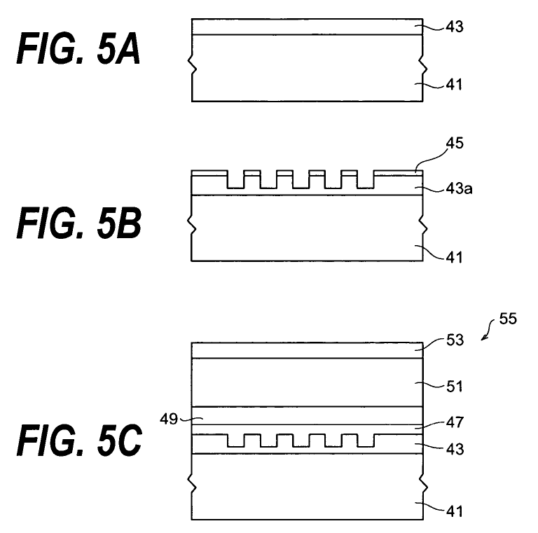

Next, the process for manufacturing the DFB-LD of the present invention will be described. FIG. 5A shows a process to form the n-type InP region. First, the n-type INP layer 43 is grown on the substrate 41 by the Organo-Metallic Vapor Phase Epitaxy (OMVPE) technique. FIG. 5B illustrates a process for forming the feedback grating. A mask 45, which may be apatterned silicon dioxide (SiO₂), placed on the InP layer 43 to form the undulation for the feedback grating. To etch the InP layer 43 by using the mask 45 lefts the undulation with a depth of about 15 nm. The mask is removed after this etching.

The n-type AlGaInAs layer 47 is grown on the patterned InP layer 43a as shown in FIG. 5C. It is preferable for a thickness of the n-type AlGaInAs layer to be around 30 nm or more to bury the undulation with a 15 nm depth in the InP layer 43. The surface of the InP layer 43 or the patterned InP layer 43a is exposed until the n-type AlGaInAs is grown thereon, during which an n-type impurities such as silicon (Si) may be transported onto the exposed surface of the InP layer 43 from the ambient or the tools made of silica glass. The Si behaves, within the InP layer, as an n-type dopant. However, the InP layer 43 is the n-type layer. Therefore, even the n-type dopant is transported into the n-type semiconductor layer, the conductivity of the n-type layer does not reduce.

Subsequently, the active region 49 is grown in the n-type AlGaInAs layer 47. The active region may be configured as shown in FIG. 2. On the active region 49 is sequentially grown with the p-type layer 51 and the p-type contact layer 53. The semiconductor regions put the active region 49 therebetween may operate as cladding layers. Thus, the epitaxial growth has completed to obtain the substrate 55 with a series of semiconductor layers grown thereon.

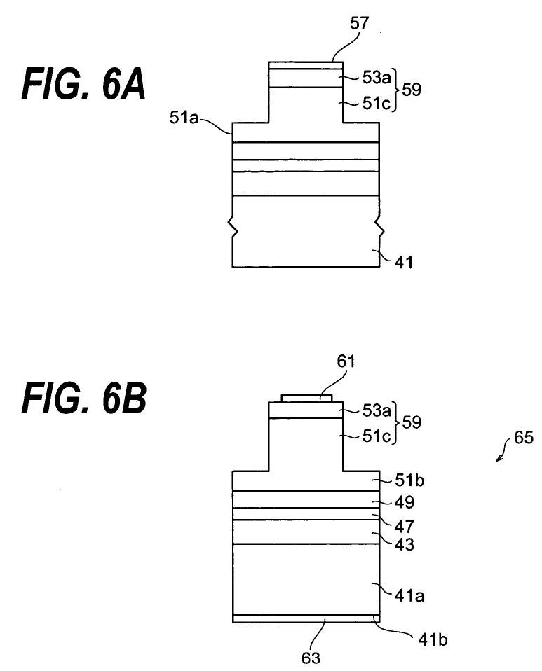

Next, FIG. 6A shows the process for forming the ridge waveguide 59. First, a mask 57, may be made of patterned silicon dioxide (SiO₂), is formed on the p-type contact layer 53. The p-type contact layer 53 and the p-type layer 51 are etched by using this mask 57 to form the p-type layer 51a and the contact layer 53a. The p-type layer 51 includes the planar portion 51b and the ridge portion 51c. The planar portion 51b is left at the etching so as to protect the whole surface of the active region 49 from the etching damage or the contamination due to the etchant. For example, the planar portion 51b is left with 0.15 μm thickness thereof for the original thickness of 2.0 μm in the layer. The ridge portion 51c and the contact layer 53a constitute a ridge stripe 59. After the formation of this ridge stripe 59, the etching mask 57 is removed.

FIG. 6B illustrates a process for forming electrodes. On the contact layer 53a is formed with the p-type electrode 61 made of, for example, titanium (Ti), platinum (Pt), and gold (Au) While, the n-type electrode 63 is formed on the back surface of the substrate 41 after grinding the substrate 41 to the thickness thereof about 100 μm. The n-type electrode is made of, for example, multi-layered metals of AuGe eutectic metal, nickel (Ni), and gold (Au). By cleaving the LD thus completed and forming an anti-reflecting film with the reflectivity below 1 % on one cleaved edge surface, while a high-reflecting film with the reflectivity greater than 80 %, the DFB-LD is completed. This LD, including AlGaInAs in the well and barrier layer in the active region, and the combination of AlGaInAs and InP in the feedback grating, shows a superior performance especially in high temperatures. The DFB-LD of the present invention can emit light in a single mode even at 100° C.

The embodiment thus described concentrates on the ridge waveguide structure. However, the feedback grating of the present invention may be applied to an LD with the buried hetero-structure. Moreover, the feedback grating may be the λ/4 shift type. In this case, anti-reflecting films may be formed on both cleaved edge surfaces.

While particular embodiments of the present invention have been shown and described, it will be obvious to those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims.

What is claimed is:

1. A light-emitting device, comprising:
an n-type InP region;
an n-type AlGaInAs layer disposed on the n-type InP region, the n-type AlGaInAs layer forming a feedback grating at an interface to the n-type InP region; and
an active region disposed on the n-type AlGaInAs layer, the active region being optically coupled with the feedback grating.

2. The light-emitting device according to claim 1,
wherein a band gap wavelength of the n-type AlGaInAs layer is greater than 1.07 μm.

3. The light-emitting device according to claim 1,
wherein a band gap wavelength of the n-type AlGaInAs layer is shorter than 1.2 μm.

4. The light-emitting device according to claim 3,
wherein a band gap wavelength of the n-type AlGaInAs layer is greater than 1.07 μm.

5. The light-emitting device according to claim 1,
wherein the active region includes a first graded layer, a first separated confinement hetero-structure layer, a multiple quantum well region, a second separated confinement hetero-structure layer, a second graded layer, and a p-type layer on the n-type AlGaInAs layer in this order.

6. The light-emitting device according to claim 5, wherein the first graded layer, a first separated confinement hetero-structure layer, a second separated confinement hetero-structure layer, a second graded layer are made of AlGaInAs.

7. The light-emitting device according to claim 5,
wherein the quantum well region includes a plurality of well layers made of AlGaInAs with a first composition and a plurality of barrier layers made of AlGaInAs with a second composition different to the first composition, wherein a band gap wavelength of the well layers is in a 1.3 μm band.

8. The light-emitting device according to claim 7,
wherein the band gap wavelength of the well layers is 1.4 μm.

9. A semiconductor laser, comprising:
an n-type InP substrate;
an n-type AlGaInAs layer;
an active region including,
a first graded layer made of AlGaInAs,
a first separated confinement hetero-structure layer made of AlGaInAs,
a quantum well region;
a second separated confinement hetero-structure layer made of AlGaInAs,
a second grated layer made of AlGaInAs,
an AlInAs layer;
a p-type InP layer; and
a p-type InGaAs layer,
wherein a band gap wavelength of the n-type AlGaInAs layer is greater than 1.07 μm and smaller than 1.2 μm.

10. The semiconductor laser according to claim 9,
wherein the p-type InP layer ridge waveguide structure including a planar portion and a stripe portion disposed on the planar portion, the planar portion covering an entire surface of the AlInAs layer.

11. The semiconductor laser according to claim 9,
wherein the quantum well region includes a plurality of well layers made of AlGaInAs with a first composition and a plurality of barrier layers made of AlGaInAs with a second composition different to the first composition, and
wherein a band gap wavelength of the well layers is in a 1.3 μm band.

12. The semiconductor laser according to claim 11, wherein the band gap wavelength of the well layers is 1.4 μm.
